(19) United States
(12) Patent Application Publication
(10) Pub. No.: US 2006/0065925 A1
(43) Pub. Date: Mar. 30, 2006

(54) Vertical MOSFET

(75) Inventor: Shogo Yoshida, Shiga (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/234,245

(22) Filed: Sep. 26, 2005

(30) Foreign Application Priority Data
Sep. 29, 2004 (JP) 2004-283489

(51) Int. Cl. H01L 29/76

(52) U.S. Cl. 257/329

(57) ABSTRACT

A vertical MOSFET includes a gate electrode formed inside a trench in a semiconductor layer, an interlayer insulating film formed above the semiconductor layer, a source electrode formed above the interlayer insulating film and electrically connected to a source region of the semiconductor layer through a conductive plug filled in a contact hole of the interlayer insulating film, and a protection diode having one end electrically connected to the source electrode and another end connected to the gate electrode through a gate metal line and including a plurality of PN junctions. The protection diode is formed inside a depressed portion in the semiconductor layer.

### BACKGROUND OF THE INVENTION

1. Field of the Invention

The present invention relates to a vertical metal-oxide-semiconductor field-effect transistor (MOSFET).

2. Description of Related Art

A vertical MOSFET having a trench gate structure where a gate electrode is formed inside a trench is known. A vertical MOSFET disclosed in Japanese Unexamined Patent Publication No. 2003-318396 (Kobayashi) has the trench gate structure and further has a conductive plug that is formed in a contact hole of an interlayer insulating film. The conductive plug electrically connects a source electrode to a source region. FIG. 6 shows the structure of the vertical MOSFET 100 taught by Kobayashi.

The vertical MOSFET is composed of a plurality of unit cells on an N+ silicon substrate 1. FIG. 6 shows the case where a single unit cell is formed on the silicon substrate. An N− epitaxial layer 2 is formed on the silicon substrate 1. A P base region 3 and an N+ source region 4 are successively formed on the surface of the epitaxial layer 2. Further, a trench 5 that penetrates through the source region 4 and the base region 3 to reach the epitaxial layer 2 is formed in a predetermined area above the silicon substrate 1. A gate oxide film 6 is formed on the inner surface of the trench 5 and on the source region 4. A gate electrode 7 is buried in the trench 5. An interlayer insulating film 8 is formed on the gate electrode 7. A contact hole 9 that penetrates through the interlayer insulating film 8 and the source region 4 to reach the base region 3 is formed between the adjacent trenches 5. A barrier metal 10 is formed on the inner surface of the contact hole 9 and on the interlayer insulating film 8. A conductive plug 11 is buried in the contact hole 9. A source electrode 12 is formed on the interlayer insulating film 8 and the conductive plug 11. Further, a drain electrode 13 is formed on the rear side of the silicon substrate 1.

FIG. 7 is a sectional view to describe a manufacturing method for a vertical MOSFET. As shown in FIG. 7, the N− epitaxial layer 2 is grown on the surface of the N+ silicon substrate 1. After that, an oxide film (SiO2) is formed by thermal oxidation. Then, a nitride film (Si3N4) and an oxide film are deposited by CVD, though not shown. The composite film is patterned by photolithography. Then, silicon etching is performed by using the composite film as a mask, thereby forming the trench 5 in the epitaxial layer 2. The composite film is etched away after forming the trench 5. After that, the gate oxide film 6 is formed on the inner surface of the trench 5 and on the surface of the epitaxial layer 2 by thermal oxidation. Then, a polysilicon film 14 is formed entirely above the semiconductor substrate 1 by CVD.

The polysilicon film 14 is etched back to remove an unnecessary part as shown in FIG. 8. The polysilicon film 14 is thereby selectively left inside the trench 5. The polysilicon film 14 in the trench 5 serves as the gate electrode 7. Further, a chip of the MOSFET requires a gate line for extension (referred to hereinafter as the gate polysilicon line) and a protection diode. Thus, patterning by photolithography is performed in the area different from a cell area, though not shown. After that, B (boron) or BF2 (boron fluoride) ion implantation and thermal treatment in oxygen or nitrogen atmosphere are performed.

The P base region 3 having a smaller depth than the trench 5 is thereby formed. Further, As (arsenic) ion implantation and thermal treatment in nitrogen atmosphere are performed on the surface of the base region 3. The N+ source region 4 is thereby formed.

Then, the interlayer insulating film 8 is formed by CVD as shown in FIG. 9. After that, a predetermined mask is formed by photolithography, and etching of the interlayer insulating film 8 and etching of the silicon are performed successively. The contact hole 9 that penetrates through the source region 4 to reach the base region 3 is thereby formed. After that, the barrier metal 10 made of Ti (titanium) and TiN (titanium nitride) is deposited by sputtering. Further, W (tungsten) is deposited on the barrier metal 10 and then etched back. W is left inside the contact hole 9 in plug from, thereby forming the conductive plug 11.

Then, AlSi (aluminum silicon) or AlSiCu (aluminum silicon copper) is deposited by sputtering, thereby forming the source electrode 12 as shown in FIG. 6. AlSi or AlSiCu is used as a source electrode 12, a gate line in contact with the gate electrode 7 (referred to hereinafter as the gate aluminum line), and a gate bonding pad. Thus, it is patterned by photolithography and etched in the area different from a cell area, though not shown. The barrier metal 10 is also etched at this time. After that, cover material such as PSG or nitride film is deposited as an overcoat. The overcoat is patterned by photolithography and etched to form a bonding region or the like. After that, the rear surface of the silicon substrate 1 is ground by a desired thickness. Several kinds of metals are evaporated and deposited onto the rear surface of the silicon substrate, thereby forming the drain electrode 13.

FIGS. 6 to 9 show a cell area only. An actual MOSFET preferably has a bi-directional zener diode or the like between the gate and source. The zener diode is a protection diode to provide protection against surge damage or the like. Japanese Unexamined Patent Publication No. 2002-373988 (Takaishi et al.) describes a vertical MOSFET that has a built-in protection diode. The vertical MOSFET is described hereinafter with reference to FIGS. 10 to 13. FIG. 10 is a plan view of the vertical MOSFET. A gate aluminum line 109 is formed as a gate finger in the periphery of and in a part of a source electrode 107. A wire bonding portion 109a is connected to the gate aluminum line 109. The gate aluminum line 109 has a connecting portion 109b that is partially projected to the inner side. The source electrode 107 has a wire bonding portion 107a and a connecting portion 107b. The connecting portion 109b of the gate aluminum line 109 and the connecting portion 107b of the source electrode 107 are formed so as to alternately engage with each other. Though the engagement of the connecting portion 109b with the connecting portion 107b is formed throughout the periphery of the chip, only a part of it is shown in FIG. 10, omitting the rest with chain lines.

FIG. 11 is a sectional view along line XI-XI in FIG. 10. In FIG. 11, an N epitaxial layer 101 is formed on an N+ semiconductor substrate 101a. A P base region 102 is formed on the surface of the N epitaxial layer 101. An N+ source region 103 is formed on the surface of the P base region 102. A trench 111 that penetrates through the source region 103 and the base region 102 to reach the epitaxial layer 101 is formed. On the inner surface of the trench 111, a gate oxide film 104 is formed. In the trench 111, a gate electrode 105 made of polysilicon is formed. Further, a depressed portion 112 is formed at the same time as the trench 111. On the inner surface of the depressed portion 112 is an oxide film 104a that is formed in the same time as the gate oxide film 104. In the depressed portion 112, a gate polysilicon line 105a is formed at the same time as the gate electrode 105. An insulating film 106 is formed on the gate electrode 105 and the gate polysilicon line 105a. A source electrode 107 is formed on the insulating film 106. The source electrode 107 is electrically connected to the source region 103 and the base region 102 through a contact hole formed in the insulating film 106. A gate aluminum line 109 is also formed on the insulating film 106 at the same time as the source electrode 107. The gate aluminum line 109 is electrically connected to the gate polysilicon line 105a through the contact hole formed in the insulating film 106.

FIG. 12 is an enlarged plan view of the engaging part of the connecting portion 107b of the source electrode 107 and the connecting portion 109b of the gate aluminum line 109 shown in FIG. 10. The part indicated between the dotted lines is a protection diode 115. The protection diode 115 is located around the periphery of the source electrode 107. FIG. 13 is a sectional view along line XIII-XIII in FIGS. 10 and 12. As shown in FIG. 13, the protection diode 115 is formed circularly by polysilicon film on the insulating film 106 in a field area located all around the periphery of the chip. In the polysilicon film, N layers 115a and P layers 115b are placed alternately in circular form. A plurality of PN junctions are thereby formed laterally in line, thereby constituting a bi-directional zener diode as the protection diode 115.

An insulating film 106a is formed on the protection diode 115. The insulating film 106a is patterned into a predetermined shape to have a contact hole. The source electrode 107 is electrically connected to the N layer 115c in the innermost periphery of the protection diode 115, and the gate aluminum line 109 is electrically connected to the N layer 115d in the outermost periphery of the protection diode 115. Thus, the gate aluminum line 109 is located outside of the gate polysilicon line 105a. In order to electrically connect the gate aluminum line 109 and the gate polysilicon line 105a, the connecting portion 107b of the source electrode 107 with the protection diode 115 and the connecting portion 109b of the gate aluminum line 109 with the gate polysilicon line 105a are projected to the protection diode 115 alternately. The gate aluminum line 109 is thereby electrically connected to the N layer 115d in the outermost periphery of the protection diode 115 and to the gate polysilicon line 105a.

Japanese Unexamined Patent Publication No. 2002-208702 describes another example of MOSFET having a built-in protection diode. The MOSFET is described hereinafter with reference to FIGS. 14 and 15. FIG. 14 is a plan view of the protection diode. FIG. 15 is a sectional view along line XV-XV in FIG. 14. For convenience, FIG. 14 does not illustrate a passivation film 10PP that is illustrated in FIG. 15. A zener diode 11PP is formed as a protection diode on an insulating film 7PP. The insulating film 7PP is formed on an N− epitaxial layer 8PP, and the epitaxial layer 8PP is formed on an N+ semiconductor substrate 9PP. The zener diode 11PP centers on an N+ layer 1PP1. P layers and N+ layers are formed successively so as to surround the N+ layer 1PP1. In FIG. 15, a P layer 31PP, N+ layer 32PP, P layer 33PP, and N+ layer 1PP2 are formed successively surrounding the N+ layer 1PP1. A passivation film 10PP is formed on the zener diode 11PP. A source electrode 5PP is electrically connected to the outermost N+ layer 1PP2, and a gate bonding pad 6PP is electrically connected to the innermost N+ layer 1PP1, respectively, through a contact hole formed in a predetermined position of the passivation film 10PP.

Use of the protection diode as shown in FIGS. 12 and 13 as a protection diode of a vertical MOSFET where a gate electrode is formed in a trench and a source electrode is connected to a source region through a conductive plug in a contact hole formed in an interlayer insulating film raises the following problem. As shown in FIG. 9, when forming the conductive plug 11, W is deposited on the interlayer insulating film 8 by CVD. Then, W is etched back so that W is left in the contact hole 9 in plug form. If the interlayer insulating film 8 is uneven, residue of W can remain in the uneven part after the etch-back of W. As described above, the protection diode 115 is formed on the insulating film 106 and the insulating film 106a is further formed thereon. Thus, unevenness occurs in the insulating film 106a at the peripheral edge of the protection diode 115. As shown in FIG. 12, the connecting portion 107b of the source electrode 107 and the connecting portion 109b of the gate aluminum line 109 are projected to the protection diode alternately. Hence, the connecting portion 107b of the source electrode 107 and the connecting portion 109b of the gate aluminum line 109 are formed also in the uneven part of the interlayer insulating film 106. Therefore, if the protection diode 115 is applied to the vertical MOSFET 100, residue can remain in the uneven part of the interlayer insulating film 106 when etching back W. If residue of W occurs, W is not etched by etching of AlSi or AlSiCu to form the source electrode and the gate aluminum electrode. As a result, the barrier metal 10 made of Ti and TiN placed therebelow is also left. If W and Ti remain in the uneven part between the connecting portion 107b and the connecting portion 109b, electrical short-circuit can occur between the gate and source. Similarly, in the zener diode 11PP shown in FIGS. 14 and 15, unevenness occurs in the insulating film 10PP on the peripheral edge of the outermost N+ layer 1PP2. As shown in FIG. 14, the source electrode 5PP and the gate aluminum line to extend the gate bonding pad 6PP are formed also on the uneven part of the insulating film 10PP. Thus, application of the zener diode 11PP to the vertical MOSFET can also raise the same problem.

### SUMMARY OF THE INVENTION

According to an aspect of the present invention, there is provided a vertical MOSFET that includes a gate electrode formed inside a trench in a semiconductor layer, an interlayer insulating film formed above the semiconductor layer, a source electrode formed above the interlayer insulating film and electrically connected to a source region of the semiconductor layer through a conductive plug filled in a contact hole of the interlayer insulating film, and a protection diode having one end electrically connected to the source electrode and another end connected to the gate electrode through a gate metal line and including a plurality of PN junctions, wherein the protection diode is formed inside a depressed portion in the semiconductor layer.

### BRIEF DESCRIPTION OF THE DRAWINGS

The above and other objects, advantages and features of the present invention will be more apparent from the following description taken in conjunction with the accompanying drawings, in which:

FIG. 1 is a plan view of a vertical MOSFET of an embodiment of the invention;

FIG. 2 is an enlarged plan view of a cell subset shown in FIG. 1;

FIG. 3 is an enlarged plan view of a gate pad portion shown in FIG. 1;

FIG. 4A is a sectional view along line IVA-IVA of the cell subset shown in FIG. 2;

FIG. 4B is a sectional view along line IVB-IVB of a gate pad portion shown in FIG. 3;

FIG. 5 is a sectional view along line V-V of a gate pad portion shown in FIG. 3;

FIG. 6 shows the structure of a vertical MOSFET;

FIG. 7 is a sectional view to describe a manufacturing method for a vertical MOSFET;

FIG. 8 is a sectional view to describe a manufacturing method for a vertical MOSFET;

FIG. 9 is a sectional view to describe a manufacturing method for a vertical MOSFET;

FIG. 10 is a plan view of a conventional vertical MOSFET;

FIG. 11 is a sectional view along line XI-XI in FIG. 10;

FIG. 12 is an enlarged plan view of an engaging part of a connecting portion of a source electrode and a connecting portion of a gate aluminum line shown in FIG. 10;

FIG. 13 is a sectional view along line XIII-XIII in FIG. 12;

FIG. 14 is a plan view of a protection diode; and

FIG. 15 is a sectional view along line XV-XV in FIG. 14.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

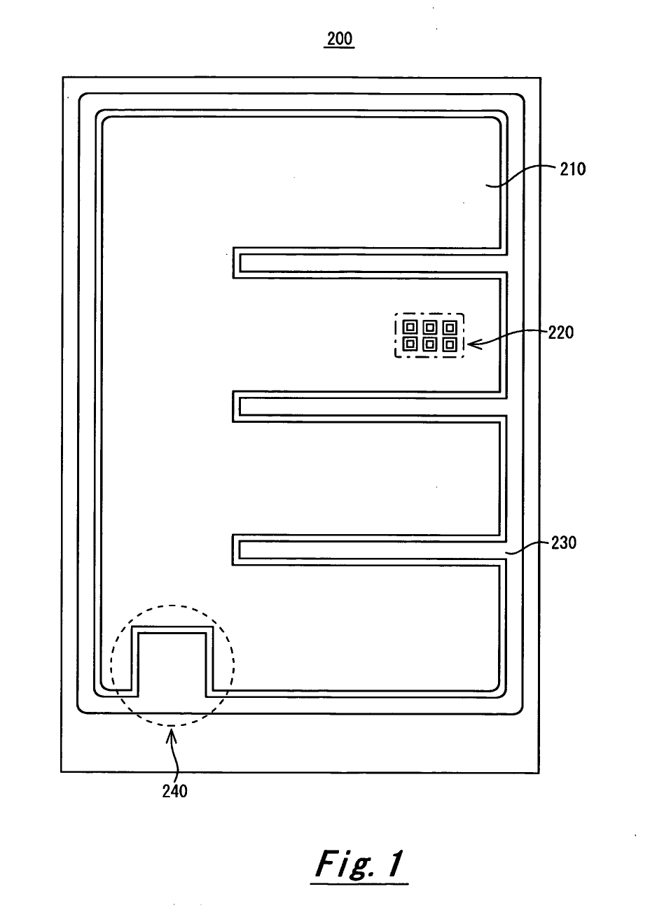

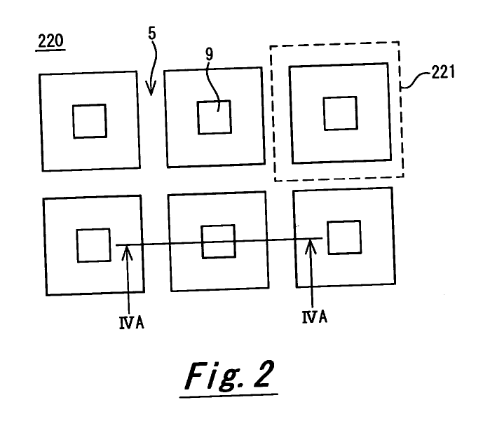

A vertical MOSFET 200 of an embodiment of the present invention is described hereinafter. FIG. 1 is a plan view of the vertical MOSFET 200. The vertical MOSFET 200 has a source electrode portion 210, a cell subset 220, a gate line 230, and a gate pad portion 240. The cell subset 220 is a part of a cell area composed of a plurality of unit cells which is placed immediately below the source electrode. FIG. 2 is an enlarged plan view of the cell subset 220 shown in FIG. 1, in which a plurality of unit cells 221 are arranged in a matrix. The unit cell 221 is defined for convenience as a quadrangular cell separated from each other by a trench 5. The unit cell 221 has a contact hole 9 at its center. Though FIG. 2 shows the case where a plurality of quadrangular cells are arranged in a matrix, the shape and arrangement of the unit cells are not limited thereto. For example, the cell arrangement may be such that the quadrangular cells in rows are displaced. Further, the cell shape may be polygonal such as hexagonal, circular, linear, or the like.

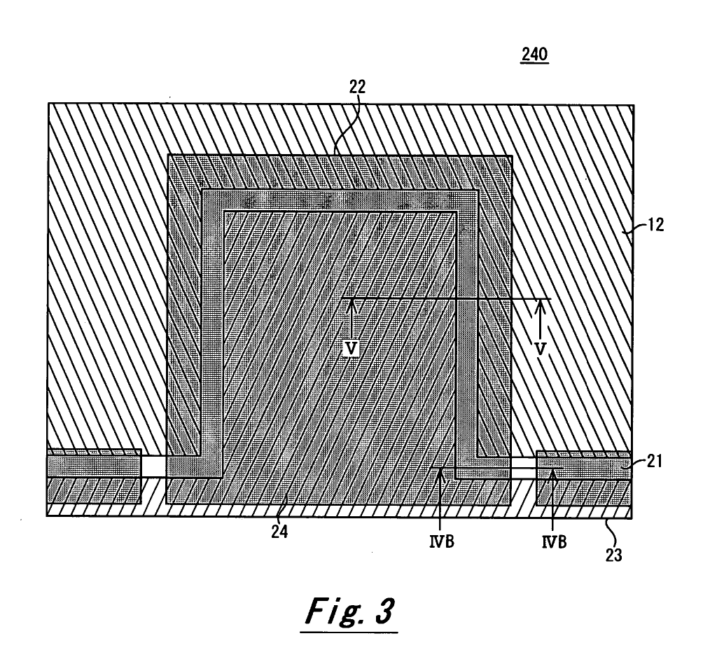

FIG. 3 is an enlarged plan view of the gate pad portion 240 shown in FIG. 1. The gate pad portion 240 has a gate polysilicon line 21, a protection diode 22, a gate aluminum line 23, and a gate bonding pad 24. The protection diode 22 is formed by polysilicon in a quadrangular shape. The gate aluminum line 23 is formed on the gate polysilicon line 21. The gate bonding pad 24 is formed in a quadrangular shape. The three sides of the gate bonding pad 24 that project inward of the chip, which are the three sides that are adjacent to the source electrode 210, are formed so as not to overlap with the three sides of the protection diode 22 that project inward of the chip. The gate polysilicon line 21 and the gate aluminum line 23 are electrically connected to form a gate line 230. The protection diode 22 has a plurality of PN junctions in circular form to constitute a bi-directional zener diode between the gate bonding pad 24 and the source electrode 12. One end of the protection diode 22 is in a central part and the other end is in a peripheral part. The central part of the protection diode 22 is electrically connected to the gate bonding pad 24. The peripheral part of the protection diode 22 is electrically connected to the source electrode 12. The source electrode 12 is placed so as to surround the three sides of the bonding pad 24 inside the chip with a predetermined distance therebetween. The gate aluminum line 23 is integrally formed with the gate bonding pad 24. The gate aluminum line 23 is also placed with a predetermined distance from the source electrode 12.

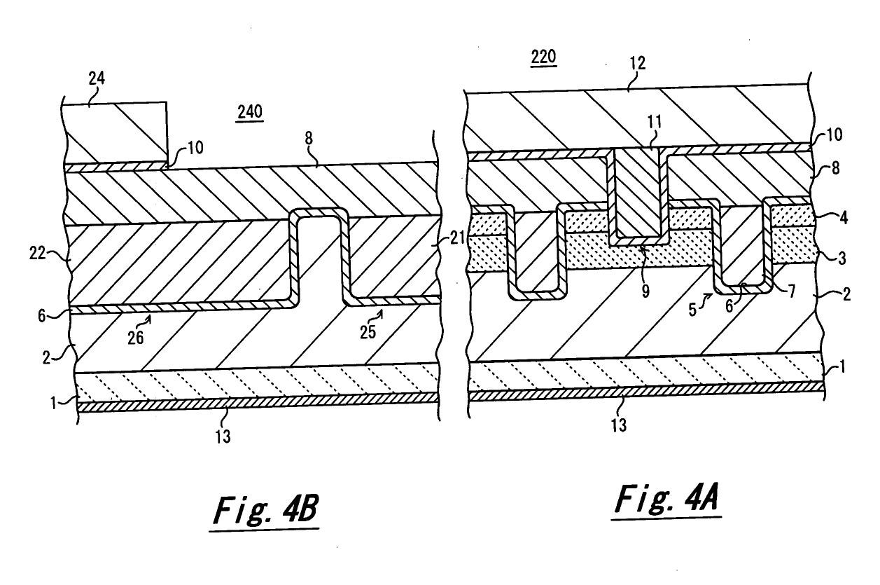

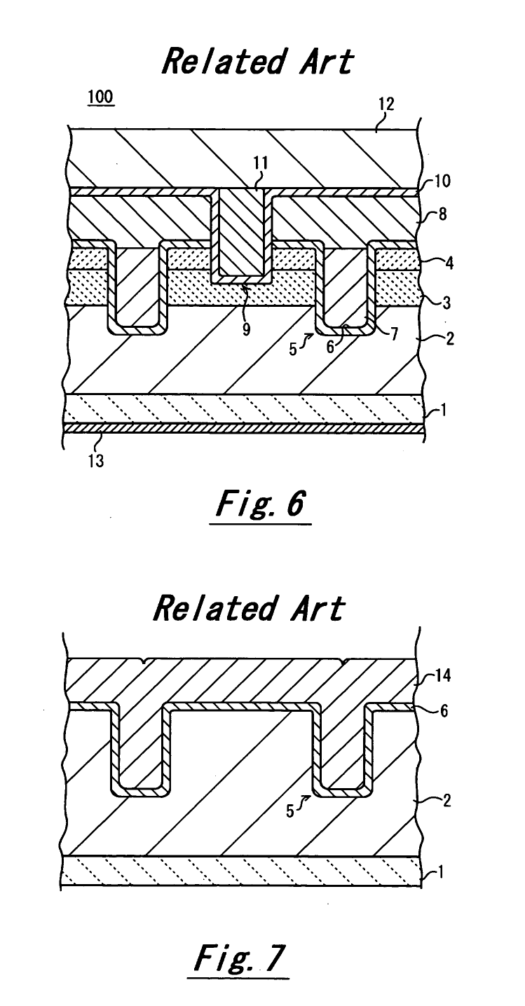

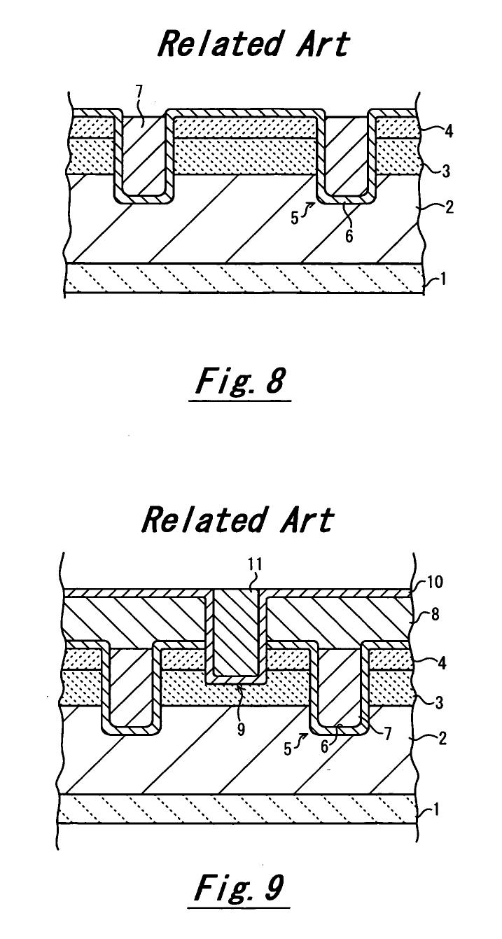

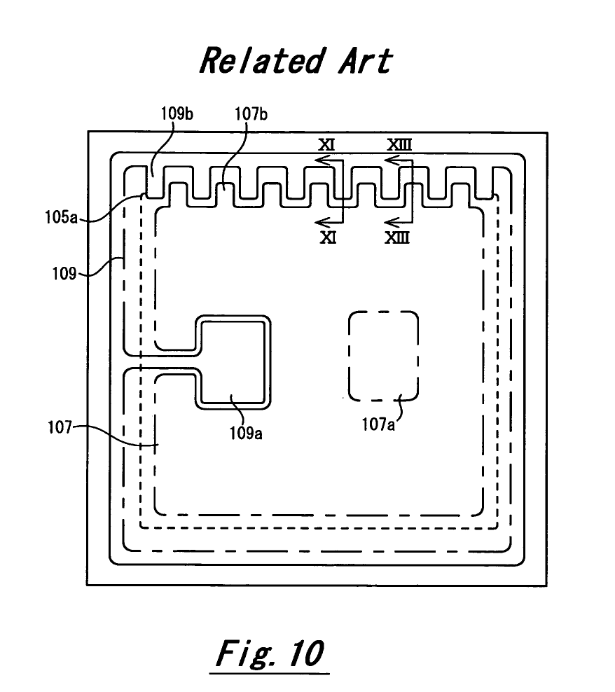

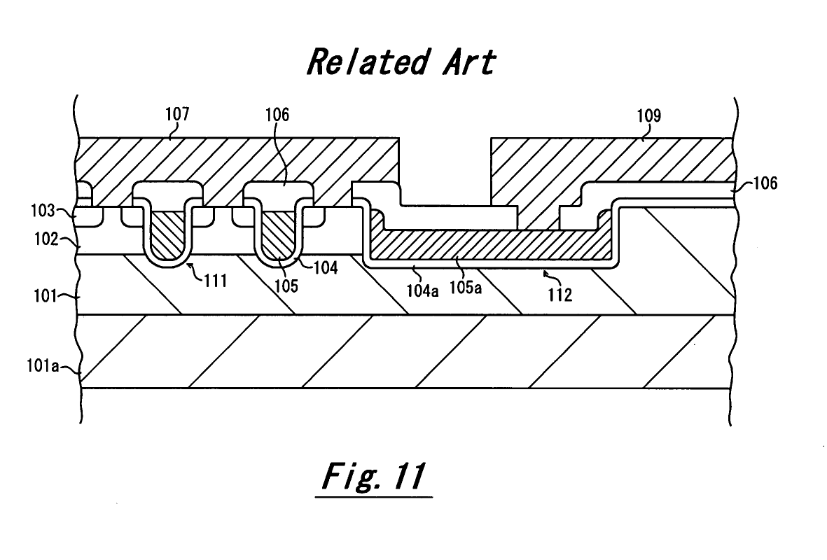

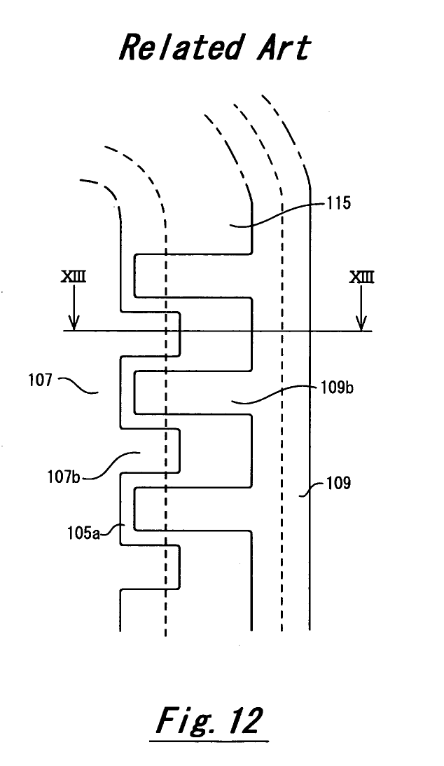

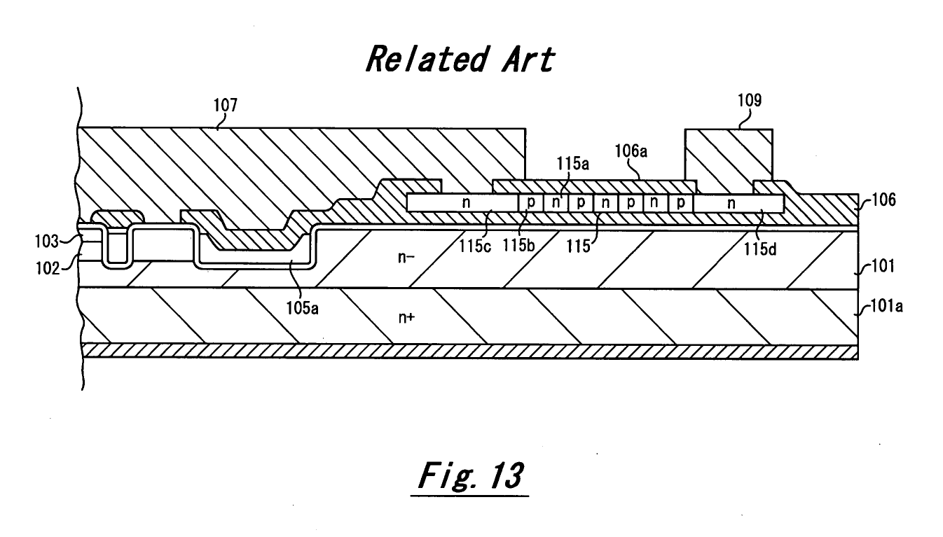

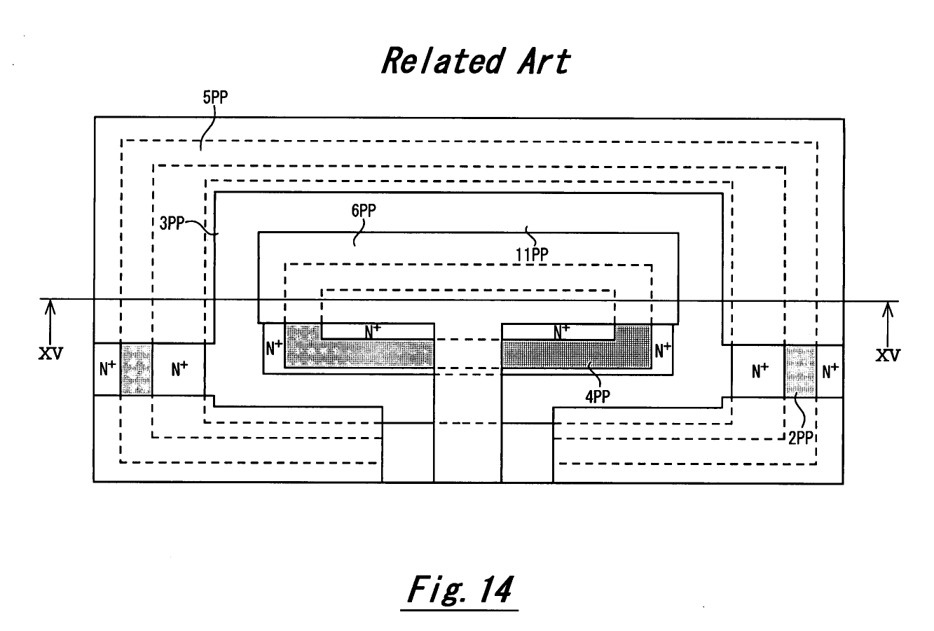

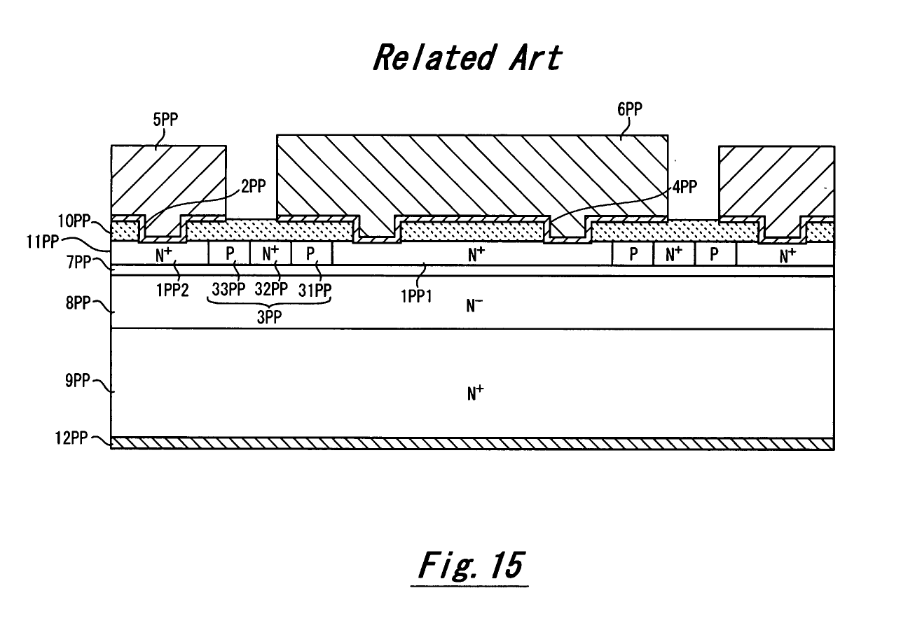

FIG. 4A is a sectional view along IVA-IVA of the cell subset 220 shown in FIG. 2. FIG. 4B is a sectional view along line IVB-IVB of the gate pad portion 240 shown in FIG. 3. The sectional view of the cell subset 220 is the same as the sectional view of the vertical MOSFET 100 shown in FIG. 6 and thus not described here. In FIG. 2, illustration of the gate electrode 7, the interlayer insulating film 8, the conductive plug 11 and the source electrode 12, which are illustrated in FIG. 4A, is omitted. In the following, the detailed structure of the gate bonding pad portion 240 is described with reference to FIG. 4B. In the cross-section along line IVB-IVB of the gate pad portion 240, the epitaxial layer 2 has depressed portions 25 and 26. The gate oxide film 6 is formed on the inner surfaces of the depressed portions 25 and 26. Further, a polysilicon film is buried in each of the depressed portions 25 and 26 on the gate oxide film 6. The polysilicon film buried in the depressed portion 25 serves as the gate polysilicon line 21 and the polysilicon film buried in the depressed portion 26 serves as the protection diode 22. The interlayer insulating film 8 is formed on the polysilicon films. The gate bonding pad 24 is formed above the interlayer insulating film 8 with the barrier metal 10 interposed therebetween. As shown in FIG. 4B, the gate bonding pad 24 is placed so that its peripheral part does not overlap with the protection diode 22. Further, the depressed portion 25 is continuous with the trench 5 where the gate electrode is formed, and the gate polysilicon line 21 is continuous with the gate electrode 7, though not shown.

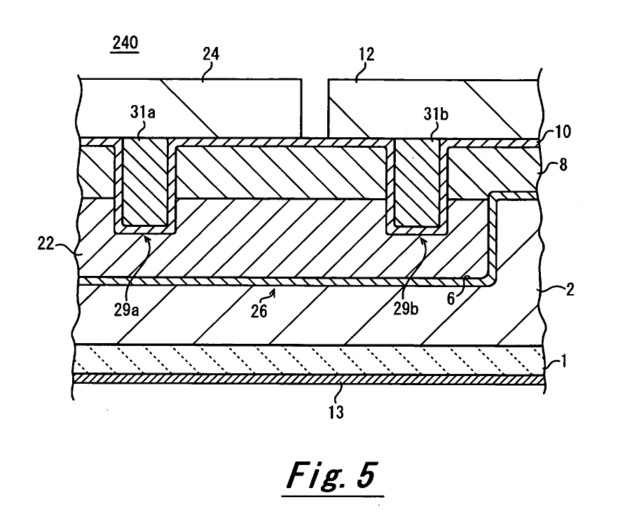

FIG. 5 shows a sectional view along line V-V of the gate bonding pad portion 240 shown in FIG. 3. In the cross-section along line V-V of FIG. 5, the epitaxial layer 2 has the depressed portion 26. The depressed portion 26 is formed at the same time as the depressed portion 26 of FIG. 4B. Thus, the gate oxide film 6 is formed on the inner surface of the depressed portion 26. The polysilicon film, which serves as the protection diode 22, is buried in the depressed portion 26. The interlayer insulating film 8 is formed on the polysilicon film. The interlayer insulating film 8 has contact holes 29a and 29b that reach the protection diode 22. The contact hole 29a is formed in the central part of the protection diode 22. The contact hole 29b is formed in the peripheral part of the protection diode 22. The barrier metal 10 that extends onto the interlayer insulating film 8 is formed on the inner surface of the contact holes 29a and 29b. Conductive plugs 31a and 31b are buried on the barrier metal 10 in the contact holes 29a and 29b, respectively. The gate bonding pad 24 is electrically connected to the conductive plug 31a and the source electrode 12 is electrically connected to the conductive plug 31b.

A method of manufacturing the vertical MOSFET 200 is described hereinafter. A manufacturing method for each unit cell 221 is the same as that for the vertical MOSFET 100 and thus not described here. In the gate bonding pad portion 240, the depressed portions 25 and 26 are formed at the same time as the trench 5. The gate polysilicon line 21 and the protection diode 22 are formed at the same time as the gate electrode 7. Thus, they are formed by etching back the polysilicon 14 shown in FIG. 7 without photolithography patterning. This allows reducing the number of photolithography steps. The gate aluminum line 23 and the gate bonding pad 24 are formed at the same time as the source electrode 12. The depressed portions 25 and 26 or the depressed portion 26 may be formed prior to forming the trench 5, before formation of a field insulating film by LOCOS oxide film. Then, the LOCOS oxide film, instead of the gate oxide film, maybe formed in the depressed portion.

As described above, the vertical MOSFET 200 has the gate polysilicon line 21 buried in the depressed portion 25 and the protection diode 22 buried in the depressed portion 26. Therefore, unevenness of such a level that causes residue of W and Ti film to remain does not occur in the interlayer insulating film 8 at the peripheral edges of the gate polysilicon line 21 and the protection diode 22. Hence, no residue is left in the interlayer insulating film 8 on the peripheral edge of the gate polysilicon line 21 and the protection diode 22 by etch-back of W when forming the conductive plug in the contact hole. It is thereby possible to prevent short-circuit between the gate and source from occurring due to the residue or the like after photolithography patterning and etching on AlSi or AlSiCu in the formation of the source electrode 12.

The above embodiment describes the vertical MOSFET where the contact hole 9 to be filled with the conductive plug 11 penetrates through the interlayer insulating film 8 and the source region 4 to reach the base region 3. However, the contact hole 9 may penetrate only through the interlayer insulating film 8. In this case, the conductive plug 11 is electrically connected to the source region and the base region on the surface of the epitaxial layer. Further, the above embodiment describes the case where the gate bonding pad 24 is formed on the protection diode 22. However, the present invention may be applied to the case where the protection diode is formed so as to surround the outer circumference of the chip. Further, this embodiment forms a N-channel vertical MOSFET. However, it is feasible to form a P-channel vertical MOSFET by using a P+ silicon substrate, P-epitaxial layer, N base region and P+ source region. Furthermore, though the above embodiment forms the epitaxial layer 2 on the silicon substrate 1, the epitaxial layer 2 is not indispensable. When using no epitaxial layer, a base region may be formed directly on the surface of the semiconductor substrate.

It is apparent that the present invention is not limited to the above embodiment that may be modified and changed without departing from the scope and spirit of the invention.

What is claimed is:

1. A vertical MOSFET comprising:
a gate electrode formed inside a trench in a semiconductor layer;
an interlayer insulating film formed above the semiconductor layer;
a source electrode formed above the interlayer insulating film and electrically connected to a source region of the semiconductor layer through a conductive plug filled in a contact hole of the interlayer insulating film; and
a protection diode having one end electrically connected to the source electrode and another end connected to the gate electrode through a gate metal line and including a plurality of PN junctions,
wherein the protection diode is formed inside a depressed portion in the semiconductor layer.

2. The vertical MOSFET according to claim 1, wherein the source electrode and the gate metal line are formed with a predetermined distance therebetween, and the source electrode and the gate metal line are formed across a part of a peripheral edge of the protection diode.

3. The vertical MOSFET according to claim 1, wherein the gate metal line and the gate electrode are electrically connected with each other through a gate polysilicon line formed in the depressed portion in the semiconductor layer.

4. The vertical MOSFET according to claim 2, wherein the gate metal line and the gate electrode are electrically connected with each other through a gate polysilicon line formed in the depressed portion in the semiconductor layer.

5. The vertical MOSFET according to claim 4, wherein the source electrode and the gate metal line are formed with a predetermined distance therebetween, and the source electrode and the gate metal line are formed across a part of a peripheral edge of the gate polysilicon line.
